(19) United States
(12) Patent Application Publication
(10) Pub. No.: US 2015/0377971 A1
(43) Pub. Date: Dec. 31, 2015

(54) Required Available Capacity Indication for Battery Backup Unit

(71) Applicants: Joseph Keating, Broomfield, CO (US); Tai-Guang Huang, Guangzhou City (CN); Julie JoAnn Lee, Lorain, OH (US); Michael Krzywosz, Warrenville, IL (US); David Wilczewski, Lorain, OH (US)

(72) Inventors: Joseph Keating, Broomfield, CO (US); Tai-Guang Huang, Guangzhou City (CN); Julie JoAnn Lee, Lorain, OH (US); Michael Krzywosz, Warrenville, IL (US); David Wilczewski, Lorain, OH (US)

(73) Assignee: ICC-NEXERGY, INC., Westchester,, IL (US)

(21) Appl. No.: 14/753,962

(22) Filed: Jun. 29, 2015

Related U.S. Application Data
(60) Provisional application No. 62/018,188, filed on Jun. 27, 2014.
(60) Provisional application No. 62/046,695, filed on Sep. 5, 2014.

(51) Int. Cl. G01R 31/36; G01K 13/00; H02J 7/00

(52) U.S. Cl. CPC G01R 31/3606; H02J 7/007; G01K 13/00

(57) ABSTRACT

A power management system is disclosed for providing an indication of the required available capacity (RAC) available from a backup battery unit (BBU) for backup or peak loading as required by a critical DC load, such as a computer bus. The power management system is configured to repeatedly determine the gross remaining capacity of the backup battery unit (BBU). The system processes this information and other measured or known battery parameters to determine the required available capacity (RAC). The RAC is based upon the required capacity of the critical load to which the BBU is connected. In general, the RAC is the difference between the gross remaining capacity of the battery at a given point in time and the required capacity of the critical load. In accordance with an important feature of the power management system, an indication of the RAC is provided. This indication can be used to indicate that the battery needs to be replaced or that the battery requires service and might indicate that the battery needs to be charged, needs to be warmed up, cooled down, etc.

### CROSS REFERENCE TO RELATED APPLICATIONS

This application claims priority to and the benefit of U.S. Provisional Patent Application No. 62/018,188, filed on Jun. 27, 2014 and U.S. Provisional Patent Application No. 62/046,695, filed on Sep. 5, 2014, hereby incorporated by reference.

### BACKGROUND OF THE INVENTION

1. Field of the Invention

The present invention relates to a power management system for providing an indication of the required available capacity (RAC) available from a backup battery unit (BBU) for backup or peak loading as required by a critical DC bad, such as a computer bus.

2. Description of the Prior Art

Backup battery systems, also known as uninterruptible power supplies (UPS), are known in the art. UPS systems are known to provide DC power to a critical load, such as computer bus. Such UPS systems are known to include a backup battery, a battery charger, a DC-DC converter and a battery management system. The battery management system, also known in the art, performs various functions including sensing the state of charge of the backup battery as well as the remaining capacity of the battery. The battery management system uses the state of charge data to control the charging of the backup battery. In such systems, it is critical that the backup battery be fully charged at all times in order to take over the supplying of DC power to the critical load. It is known that the charge on a battery decays over time. As such, the battery management system senses the open circuit voltage of the backup battery periodically to determine the state of charge. Based on the open circuit voltage measurements of backup battery, the battery management system controls the battery charger to maintain the output battery voltage of the backup battery at a predetermined value.

Normally the critical load is powered from a primary DC source. The primary DC source is known to be provided by an AC/DC converter connected to an external source of AC power. When AC power is lost or there is a component failure on the primary DC power circuit, the backup battery takes over. More specifically, the backup battery is connected to the critical load by way of a switch. The battery management system or other controller powered from the backup battery continuously sense the voltage at the critical load. When the voltage at the load is lost, the battery management system issues a signal to close the switch to connect the backup battery to the load.

An important concern with such backup batteries is the decay of battery capacity over time. The battery capacity is the amount of amp-hours or watt-hours the battery can provide at its rated voltage. The battery capacity is normally measured in amp-hours or watt-hours. Accordingly, the capacity of a battery is periodically measured to determine the available battery capacity. Measurement of battery capacity is known in the art. For example, U.S. Pat. No. 6,624,635, hereby incorporated by reference, discloses this process in detail. Systems, such as the system disclosed in the '635 patent are known to provide an indication, such as “Replace Battery”, when the gross battery capacity degrades below a predetermined threshold capacity, for example, 70% of the original.

While such a system, as described above, is useful in providing an indication of the remaining capacity of a battery, the indication has nothing to do with the load requirements. For example, the critical load may only require 60% of the gross battery capacity. In applications where the predetermined threshold of battery capacity is 70%, the backup battery in the above example would have been replaced even though the backup battery had sufficient capacity to carry the load.

Thus, there is a need for a system for providing an indication of battery capacity as a function of the bad requirements.

### SUMMARY OF THE INVENTION

Briefly, the present invention relates to a power management system for providing an indication of the required available capacity (RAC) available from a backup battery unit (BBU) for backup or peak loading as required by a critical DC bad, such as a computer bus. The power management system is configured to repeatedly determine the gross remaining capacity of the backup battery unit (BBU). The system processes this information to determine the required available capacity (RAC). The RAC is based upon the required capacity of the critical bad to which the BBU is connected, in general, the RAC is a measure of the total capacity available for client backup or peak loading operations. RAC is reported to the Client as a percentage or an appropriately unitized value (e.g. Amp-hour or watt-hours) of the specified required energy or capacity needed by the client to complete a task such as a backup event in the case of a loss of power or a need to increase the total power to the bad in case of a peak demand from the client application. In some cases, the RAC may be modified by the client to account for changes in the intended application. The RAC can be recalculated by the BBU. For example, a BBU may have an RAC specified as 100 Watt-hours. It will report 0-100% RAC depending on the availability of capacity within the battery. In accordance with an important feature of the power management system, an indication of the RAC is provided. This indication can be used to indicate the need to replace the BBU. By providing an indication of the RAC rather than the gross remaining capacity of the BBU, the indication to replace a BBU more closely fits the requirements of a critical bad. The RAC will also indicate if there is sufficient capacity to complete a task demanded by the critical bad in cases where the battery is partially discharged or cannot partially or fully support the peak power demanded by the client.

### DESCRIPTION OF THE DRAWING

These and other advantages of the present invention will be readily understood with reference to the following specification and attached drawing wherein:

FIG. 1 is an exemplary block diagram illustrating an exemplary backup battery system connected to a DC bus and also illustrating primary DC supply connected to the DC bus.

FIG. 2 illustrates the concept of the required available capacity graphically.

FIG. 3 is similar to FIG. 2 but illustrates some exemplary values.

FIG. 4 is a graphical representation of the RAC adjustment with 75° C.

FIG. 5 is a graphical representation of the RAC adjustment due to a power limit at 25° C.

FIG. 6 is a graphical representation of the RAC adjustment due to a power limit at 25° C. at 100% SOC.

FIG. 7 is a graphical representation of the RAC adjustment due to a power limit at 45° C.

### DETAILED DESCRIPTION

The present invention relates to a power management system for providing an indication of the required available capacity (RAG) available from a backup battery unit (BBU) for backup or peak loading as required by a critical DC load, such as a computer bus. The power management system is configured to repeatedly determine the gross remaining capacity of the backup battery unit (BBU). The system processes this information to determine the required available capacity (RAC). The RAC is based upon the required capacity of the critical load to which the BBU is connected. In general the RAG is a measure of the total capacity available for client backup or peak loading operations. RAC may be reported to the Client as a percentage or an appropriately unitized value (e.g. Amp-hour or watt-hours) of the specified required energy or capacity needed by the client to complete a task, such as a backup event in the case of a loss of power or a need to increase the total power to the load in case of a peak demand from the client application. In some cases, the RAC may be modified by the client to account for changes in the intended application. The RAC can be recalculated by the BBU. For example, a BBU may have an RAC specified as 100 Watt-hours. It will report 0-100% RAC depending on the availability of capacity within the battery. In accordance with an important feature of the power management system, an indication of the RAC is provided. This indication can be used to indicate the need to replace the BBU. By providing an indication of the RAC rather than the gross remaining capacity of the BBU, the indication to replace a BBU more closely fits the requirements of a critical load.

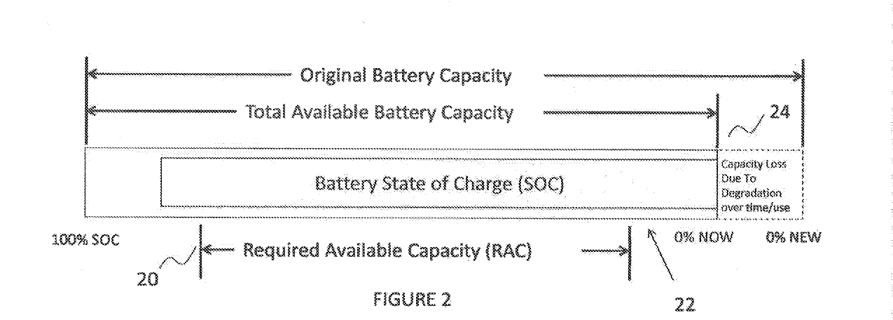

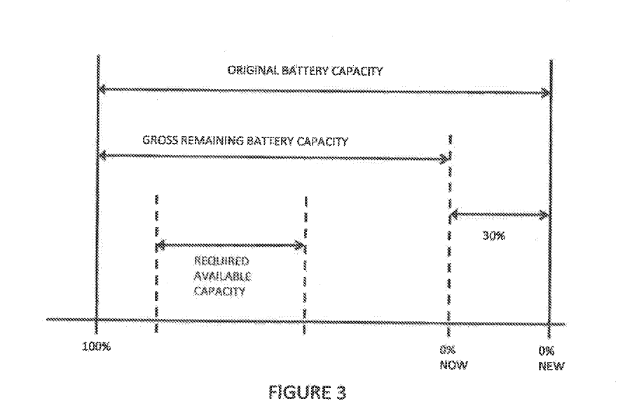

The concept of required available capacity is best understood with reference to FIGS. 2 and 3. Referring to FIG. 2 first, the top line relates to the original battery capacity. The next line relates to the total available capacity which assumes a capacity loss due to degradation over time and use. The total available gross battery capacity at a given point in time is known as the battery state of charge (SOC). The SOC is analogous to a battery fuel gauge. The SOC is the overall battery energy (capacity) that is currently available reported as a percentage of the gross (actual capacity, since the actual capacity will decrease over life of battery) battery capacity. This is different than the RAC since it requires knowledge of the total battery capacity including degradation, etc.

The RAC is an indication of the capacity that is available to the critical load as a percentage of the total specified capacity of the client application, i.e. critical load. In the example in FIG. 2, there is 100% RAC reported, even though the total available battery capacity has degraded and the battery is not at 100% SOC. In this example, the client knows that it can depend on the BBU providing 100% of the needed capability (power and capacity) on demand due to either partial or total loss of the primary power source, or due to period peak power demands where the client requests stored power from the BBU in place of power from the primary power source.

RAC is not dependent on the SOC of the total battery, unless the SOC is below the minimum energy needed to provide 100% RAC. The ability of the BBU to provide full RAC may be dependent on the power delivery capability of the battery in addition to available energy or capacity. For example, if the measured temperature of the BBU is below a certain value, the battery internal resistance may increase, which reduces the ability of the BBU to provide peak power for some or all of the RAC, which would reduce the reported RAC. It is known that some batteries have reduced power delivery capability at lower states of charge, or at lower temperatures or due to degradation due to use or aging. If a battery cannot meet both the power and energy demands, the RAC will be reduced.

100% RAC is not necessarily equal to 100% SOC. Even though the battery may be below 100% SOC, the BBU may still be able to supply 100% RAC within the available SOC. However, as the battery degrades, the BBU may still report 100% RAC assuming that there is sufficient total battery capacity available to support a 100% RAC requirement.

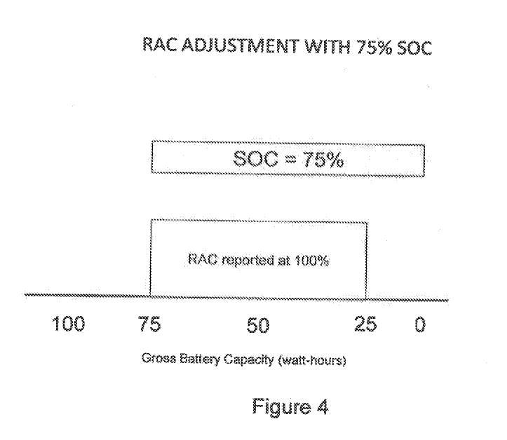

RAC can be adjusted depending on factors including temperature, load demand, battery degradation of capacity or internal resistance. For example, a cold or old battery will have a higher internal impedance. This might cause the BMS to shift the RAC range to the left in FIG. 4, since a fully charged battery has more power delivery capability than a partially charged battery, a higher SOC level might be required to report 100% RAC.

Since RAC is calculated and reported by the BBU, the client does not need to understand or compensate for battery capacity or capability calculations. This reduces the loading on the client with respect to understanding the capability of the BBU, removing considerations such as temperature, age, usage cycles, etc. from the client.

Assuming the total RAC is a fixed quantity (energy or capacity) defined by the client, it can be relocated as a subset of the gross capacity within the battery. FIG. 2 illustrates this showing the RAC as a subset of capacity located within the gross available capacity. The maximum RAC level can be equal to the maximum gross battery capacity, or could be equal to some other value depending on known battery characteristics such as temperature, gross capacity, internal resistance or battery degradation.

In conventional battery management systems, a threshold value of SOC is used to indicate the need to replace the battery. For example, as indicated in U.S. Pat. No. 6,624635, discussed above, the threshold is set at 70%. This threshold is known to be selected independent of the capacity requirements of the critical bad.

In accordance with an important feature of the BBU, the threshold is selected based upon the capacity requirements of the critical bad to which the BBU is connected. Thus, as shown in FIG. 2, the bottom line relates to the required available capacity (RAC). The RAC is used to indicate that the battery needs to be replaced or that the battery requires service and might indicate that the battery needs to be charged, needs to be warmed up, cooled down, etc. Moreover, the RAC is indicated in terms of the capacity requirements of the critical load. In particular, with reference to FIG. 2, the point 20 on the bottom line will be indicated as 100% RAC even though the battery SOC is not at 100% and is indicated as having a considerable drop in SOC due to the battery being in a partial state of charge, i.e. not fully charged. As noted from FIG. 2, the 0% point for the RAC, identified with the reference numeral 22, may be selected above the 0% of the SOC, identified with the reference numeral 24, to provide a cushion for the critical bad or reserve capacity for the battery to account for the predicted degradation.

FIG. 3 is similar to FIG. 2 but includes exemplary data. As shown the gross remaining battery capacity is shown as 70%. As indicated above, some known systems provide an indication at 70% that the backup battery needs to be replaced. In this example, the backup battery would needlessly be replaced since the threshold for the critical bad is 50%. Under certain circumstances, such as varying temperature or a change in the predicted maximum load (current), the RAC may be adjusted so that the lower SOC corresponding to the 0% indicated RAC could be changed. In FIG. 3, the 0% RAC indication could be changed to correspond to the 0% SOC value which could reduce the minimum gross remaining battery capacity amount to 30% before battery replacement would be required. The lower correlation point between SOC and RAC could also be increased.

There are several advantages and features of reporting the RAC as follows:
RAC is not dependent on the SOC of the total battery, unless the SOC is below the minimum energy needed to provide 100% RAC.
100% RAC does not have to be equal with 100% SOC. Even though the battery may be below 100% SOC, the BBU may still be able to adjust the RAC to fit within the available SOC.
As the battery degrades, the BBU can still report 100% RAC assuming that there is sufficient total battery capacity available to support a 100% RAC capability.

RAC can be adjusted depending on factors including temperature, load demand, battery degradation of capacity or internal resistance. For example, a cold or old battery will have a greater internal impedance than a newer or warmer battery. Increased internal resistance would therefore reduce the amount of energy that could be provided by the battery to the system. The RAC could then be adjusted so that it occupies a greater portion of the total battery capacity by percentage. Alternatively, it could also be located so that the RAC portion of the total battery capacity would reside at a higher relative state of charge. A newer or warmer battery would have the ability to deliver more energy to the load, resulting in an RAC setting that could be adjusted to occupy a smaller portion of the total battery capacity by percentage, or located to reside at a lower relative state of charge. These factors can be used to cause the BMS to shift the RAC range to the left in FIG. 2, since a fully charged battery has more power delivery capability than a partially charged battery, a higher SOC level might be required to report 100% RAC.

Since RAC is reported, for example, as a percentage of capability or in terms of amp-hours or watt-hours, the client does not need to understand or compensate for battery capacity or capability calculations. This reduces the loading on the client with respect to understanding the capability of the BBU, removing considerations such as temperature, age, usage cycles, etc. from the client.

As mentioned above, the RAC can also be influenced by the temperature of the battery 26. A temperature sensor 31 may be provided for measuring the temperature of the battery 26. Various types of conventional temperature sensors are suitable for this application. For example, RTD, thermistor and thermocouple type temperature sensors are suitable. The battery temperature sensor 31 sends a battery temperature signal to the Battery Management Controller 31. Based on the specifications for the specific battery 26, the Battery Management Controller 31 determines the available battery power as a function of the state of charge at the temperature determined by the battery temperature sensor 31.

FIG. 4 illustrates the RAC for a given minimum power requirement at an SOC of 75%. For example, if a given BBU has a battery with 100 Watt-hours of gross capacity, the BBU will be able the minimum power requirement even though the SOC has been determined by a conventional fuel gauge method to be 75%. Under such conditions, the RAC would then be determined to indicate 100%.

Assume a BBU 25 is shipped with a battery 26 at a partial SOC, or is left in a condition where the battery 26 self-discharges, such as when the BBU 25 is stored in a warehouse. On start-up, the BBU 25 will calculate the SOC using a fuel gauging method, discussed above, which is well known. Using the example above, e.g. 75% SOC, the BBU 25 would then be able to report the RAC at 100% assuming that sufficient SOC is available to meet the minimum power requirement of the critical load 36. In particular, if the gross battery capacity required by the critical load is 50 watt hours, the system would indicate the RAC at 100% even though the battery is not fully charged. This would allow the client to utilize the BBU immediately upon installation.

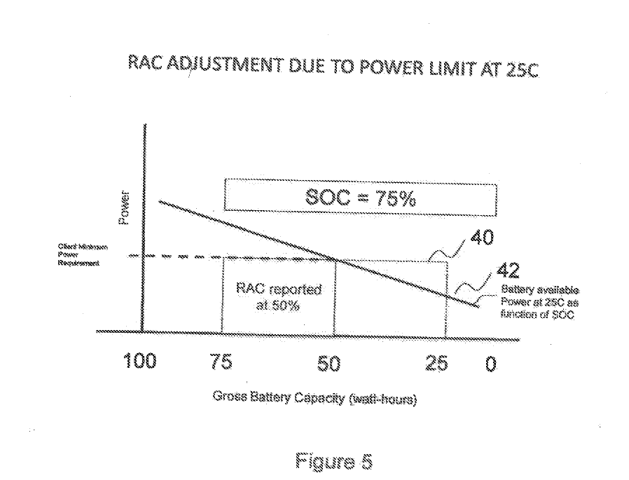

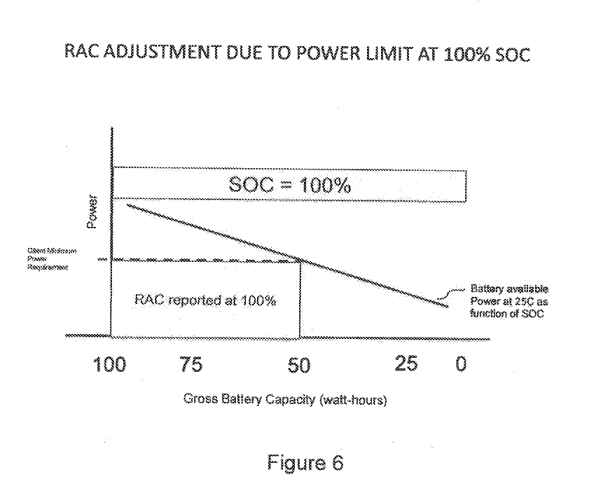

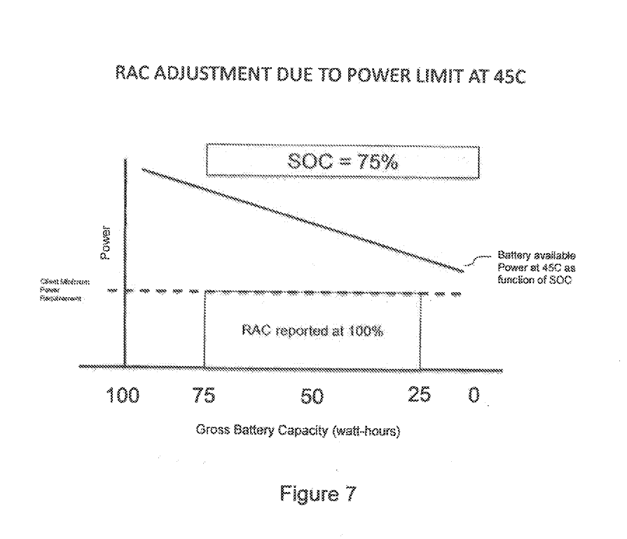

FIGS. 5-7 illustrate the RAC for supplying a minimum power requirement, e.g. 50 watt-hours, as a function of battery temperature and SOC. For example, FIG. 5 illustrates the RAC for the minimum power requirement at a battery temperature of 25° C. and a SOC of 75%. FIG. 6 illustrates the RAC for the minimum power requirement at a battery temperature of 25° C. and a SOC of 100%. FIG. 7 illustrates the RAC for the minimum power requirement at a battery temperature of 45° C. and a SOC of 75%.

In particular, FIG. 5 illustrates a graph of the client minimum power requirement in watts as a function of the gross battery capacity in watt-hours. The client minimum power requirement is assumed to be constant, as indicated by the curve 40. Assuming a battery temperature of 25° C., the available battery power curve, as indicated by the curve 42, decreases linearly as the SOC decreases. As shown, the available battery power curve 42 intersects the client minimum power requirement curve 40 at a SOC of 50%. In this example, the BBU indicates a RAC of 50%. As such, in this case, the battery will need to be charged before the BBU is put in service.

The example above could be further modified to include the current power delivery capability of the battery in addition to the current energy or capacity capability. For example, assuming that it is known for a given battery that the power delivery capability drops below the client's required threshold at 50% SOC at a temperature of 25° C. In the case above, the RAC would then be reported at 50%. FIG. 5 shows the RAC as it would be calculated with a battery at 25° C. given that the SOC is 75% taking the power capability of the battery into consideration. Alternatively, if the battery in FIG. 4 were to be fully charged (100% SOC), the maximum RAC indication could be readjusted to be equal to the maximum (100%) SOC indication. In this case, the BBU would indicate 100% RAC. This is shown in FIG. 6.

FIG. 7 shows the same battery at 45° C., where it is known that the battery power delivery capability increases at higher temperatures. In this case, the RAC could be indicated at 100% for SOC as low as 50% since the higher temperatures would increase the battery's minimum power delivery capability above the minimum value required by the client for any SOC.

Note that the power delivery capability of the battery can change due to other factors including aging or use. The same method would be employed to recalculate the RAC following these measured or known changes. These are only a few examples of how RAC can be recalculated depending on the known or measured characteristics of the battery. The declining energy or power delivery capability due to temperature, aging or use of the battery can cause the BBU to recalculate or relocate the RAC within the gross battery capacity. For example, assume a battery with 100 Watt-Hours of total or full charge capacity and a defined RAC of 50 Watt-Hours, with 50 Watt-Hours of additional or non-utilized capacity. Initially, the 50 Watt-Hour RAC might be defined as being located in the capacity region between 25-75 Watt-Hours, where 100% RAC would be available when the new battery is charged to a state of 75 Watt-Hours, and 0% RAC would be available when the new battery is discharged to a state of 25 Watt-Hours. Over the lifetime of the battery, the total battery capacity would diminish due to degradation of the battery. At one point, for example, the battery capacity could be reduced to 80 Watt-Hours from the original 100 Watt-Hours. The 50 Watt-Hour RAC could then be relocated to reside in the region between 30 and 80 Watt-Hours which would make the RAC available at a higher SOC range to overcome the potential degradation effects that result from increased internal resistance.

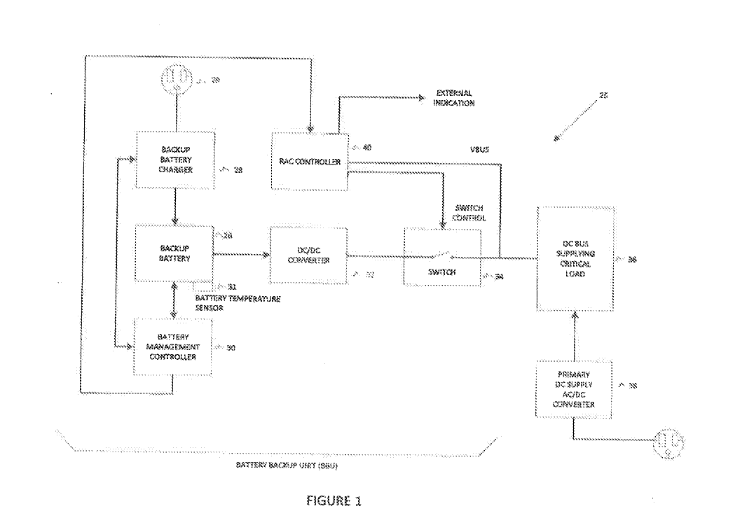

FIG. 1 illustrates an exemplary backup battery system, generally identified with the reference numeral 25, in which the RAC is used, shown connected to a critical bad 36, such as a DC bus. A primary DC supply 38 is also connected to the critical bad 36.

In general, the backup battery unit (BBU) includes a battery 26 and electronics that includes a Battery Management Controller 30 and a RAC Controller 40 that can manage the battery functions, provide recharge to the battery from a connected power source (optional), provide a regulated output from the battery (optional), and provide communications between the battery and the client. The RAC Controller 40 may be integrated into the Battery Management Controller 30. The BBU 25 supplies energy to the critical bad 36 during periods of peak power demand or when the primary power source, i.e. primary DC supply 38, is not present in order to maintain the functions of the critical bad connected to the DC bus or a period of time that is determined by the RAC.

The backup battery 26 is charged by a backup battery charger 28 that is connected to an external source of AC 29. The backup battery charger 28 maintains the charge on the backup battery, for example, in a conventional manner. The backup battery 26 is shown connected to a DC/DC converter 32, for example, a conventional DC/DC converter, which provides a regulated DC output voltage. The DC/DC converter 32 is connected to an electronic switch 34, for example, a field effect transistor (FET). The other side of the switch 34 is connected to the critical bad 36. Under normal conditions, the switch 34 is open and power is supplied to the critical bad by way of a primary DC supply 38. The primary DC supply 38 is shown as an AC/DC converter, for example, a conventional AC/DC converter, connected to an external AC supply 39.

The Battery Management Controller 30 monitors the battery characteristics and controls state of charge. It can also perform the following functions:
calculations to determine SOC, RAC, total battery capacity.
can provide some level of battery protection to prevent overcharge or over-discharge.
can provide capacity balancing between cells in series. Can report these parameters directly to a client or to an intermediate controller, such as the controller 40 either present in the BBU or the client.

The Battery Management Controller 30 senses the bus voltage. If the Battery Management Controller 30 senses a loss of voltage on the DC bus 36, the Battery Management Controller 30 signals the switch 34 to dose to connect the backup battery 26 to the DC bus.

During normal conditions, i.e. primary DC supply 38 providing power to the DC bus 36, the Battery Management Controller 30 repeatedly determines the SOC of the backup battery 28. One or the other of the Battery Management Controller 30 or the RAC controller 40 determine the RAC based on the capacity requirements of the critical load and the SOC. The RAC information may be indicated locally or externally as shown.

The minimum power requirements for the specific back-up battery are provided by the client. These minimum power requirements are stored in memory that is part of the Battery Management Controller 30. The characteristic curves for the specific back-up battery are also stored. The Battery Management Controller 30 is thus able to indicate the RAC based upon the SOC and the various battery parameters, such as battery temperature.

Obviously, many modifications and variations of the present invention are possible in light of the above teachings. Thus, it is to be understood that, within the scope of the appended claims, the invention may be practiced otherwise than as specifically described above.

What is claimed and desired to be secured by a Letters Patent of the United States is:

1. A power management system for providing an indication of the state of charge of a backup battery used for backup of a critical load in terms of the required available capacity (RAC) of the critical load, the power management system comprising:
one or more controllers for repeatedly determining the state of charge (SOC) of said backup battery, said one or more controllers configured to determine said (SOC) of said backup battery in terms of the required available capacity (RAC) of the critical load.

2. The power management system as recited in claim 1, wherein said one or more controllers are configured to provide an indication that the backup battery has 100% RAC if the SOC of the backup battery is less than 100% but greater than the RAC under predetermined conditions.

3. The power management system as recited in claim 2, wherein said one or more controllers are configured to determine said SOC of said backup battery in terms of 0 to 100% of said RAC.

4. The power management system as recited in claim 1, wherein said RAC is a fixed quantity.

5. The power management system as recited in claim 1, wherein said one or more controllers are configured to determine the RAC in terms of the SOC of the backup battery and one or more additional factors other than the SOC of the backup battery.

6. The power management system as recited in claim 5, wherein said one or more additional factors include the temperature of the battery.

7. The power management system as recited in claim 5, wherein said one or more additional factors include the internal resistance of the backup battery.

8. The power management system as recited in claim 1 further comprising:
a battery charger for charging said backup battery;
a DC-DC converter serially connected to said backup battery; and
a switch connected between said backup battery and a DC bus supplying a critical load, wherein said one or more controllers sense the voltage on the DC bus and close the switch when a loss of voltage is detected.

9. A power management system for providing an indication of the state of charge of a backup battery used for peak loading of a critical load in terms of the required available capacity (RAC) required for peak loading, the power management system comprising:
one or more controllers for repeatedly determining the state of charge (SOC) of said backup battery, said one or more controllers indicating said (SOC) of said backup battery in terms of the required available capacity (RAC) required for peak loading of a critical load.

10. The power management system as recited in claim 9, wherein said one or more controllers are configured to provide an indication that the backup battery has 100% RAC if the SOC of the backup battery is less than 100% but greater than the RAC under predetermined conditions.

11. The power management system as recited in claim 10, wherein said one or more controllers are configured to provide an indication that said SOC of said backup battery is in terms of 0 to 100% of said RAC.

12. The power management system as recited in claim 9, wherein said one or more controllers are configured to determine the RAC in terms of the SOC of the backup battery and one or more additional factors other than the SOC of the backup battery.

13. The power management system as recited in claim 12, wherein said one or more additional factors include the temperature of the battery.

14. The power management system as recited in claim 12, wherein said one or more additional factors include the peak load demand of the critical load.

15. The power management system as recited in claim 12, wherein said one or more additional factors include the internal resistance of the backup battery.

16. The power management system as recited in claim 9 further comprising:
a battery charger for charging said backup battery;
a DC-DC converter serially connected to said backup battery; and
a switch connected between said backup battery and a DC bus supplying a critical load, wherein said one or more controllers sense the voltage on the DC bus and close the switch during conditions of peak loading by the critical load.

17. A method of determining the required available capacity (RAC) of a backup battery used for backup of a critical load or peak loading, the method comprising the steps of:
(a) repeatedly determining the state of charge (300) of said backup battery;
(b) indicating the (300) of said backup battery in terms of the required available capacity (RAC) of the critical load.

18. The method as recited in claim 17, further including step (c):
(c) adjusting the RAC as a function of one or more additional factors other than the SOC of the backup battery.

19. The method as recited in claim 18, wherein step (c) comprises:
(c) adjusting the RAC as a function of the temperature of the backup battery.

20. The method as recited in claim 18, wherein step (c) comprises:
(c) adjusting the RAC as a function of the internal resistance of the backup battery.

21. A method of determining the required available capacity (RAC) of a backup battery used for backup peak loading, the method comprising the steps of:
(a) repeatedly determining the state of charge (SOC) of a backup battery;
(b) indicating the (SOC) of the backup battery in terms of the required available capacity (RAC) of the RAC required for peak loading.

22. The method as recited in claim 21, further including step (c):
(c) adjusting the RAC as a function of one or more additional factors other than the SOC of the backup battery.

23. The method as recited in claim 21, wherein step (c) comprises:
(c) adjusting the RAC as a function of the temperature of the backup battery.

24. The method as recited in claim 21 wherein step (c) comprises
(c) adjusting the RAC as a function of the internal resistance of the backup battery.

25. The method as recited in claim 21, wherein step (c) comprises:
(c) adjusting the RAC as a function of the peak load demand of the critical load.

26. In a backup battery unit (BBU), the improvement comprising:
a power management system for monitoring the state of charge (SOC) of a battery and providing an indication of the required available charge of the backup battery unit as a function of the SOC and one or more measured or known parameters to meet the required capacity of a critical load connected to a DC bus to be connected to BBU when the primary DC supply is lost.

27. The battery backup unit as recited in claim 26, wherein one of said parameters is battery temperature.
